(19) United States
(12) Patent Application Publication
(10) Pub. No.: US 2023/0243933 A1
(43) Pub. Date: Aug. 3, 2023

(54) LIGHT EMITTING DEVICE AND MEASUREMENT APPARATUS

(71) Applicant: FUJIFILM Business Innovation Corp., Tokyo (JP)

(72) Inventors: Kei TAKEYAMA, Kanagawa (JP); Junichiro HAYAKAWA, Kanagawa (JP); Takashi KONDO, Kanagawa (JP); Tomoaki SAKITA, Kanagawa (JP)

(73) Assignee: FUJIFILM Business Innovation Corp., Tokyo (JP)

(21) Appl. No.: 17/871,975

(22) Filed: Jul. 24, 2022

(30) Foreign Application Priority Data
Feb. 2, 2022 (JP) 2022-014965

(51) Int. Cl. G01S 7/484; G01S 17/10; G01S 7/4865; G01S 7/4861

(52) U.S. Cl. CPC G01S 7/484; G01S 7/4861; G01S 7/4866; G01S 17/10

(57) ABSTRACT

A light emitting device includes a light emitting unit that includes a light emitting element having a function of a thyristor; and a drive unit that performs, before a period in which light emitted from the light emitting unit is used, control such that a predetermined current or larger flows in the thyristor of the light emitting unit.

### CROSS REFERENCE TO RELATED APPLICATIONS

This application is based on and claims priority under 35 USC 119 from Japanese Patent Application No. 2022-014965 filed Feb. 2, 2022.

### BACKGROUND

### (I) Technical Field

The present invention relates to a light emitting device and a measurement apparatus.

### (II) Related Art

There is known a light emitting device that has a thyristor function and turns ON a thyristor by causing a current to flow from a gate electrode, and thus emits light.

JP2018-1523A discloses a light emitting component. The light emitting component includes a plurality of laser diodes, a plurality of control thyristors, and a light emitting setting unit. The plurality of laser diodes are set to an ON state at a logical value of “1”, and an ON state and an OFF state considered as being at a logical value of “0”. The plurality of control thyristors are stacked with the respective laser diodes. Each control thyristor sets the laser diode to turn into a state of being capable of transitioning to the ON state. The light emitting setting unit sets the control thyristor to turn into the ON state, and sets the laser diode to turn into the ON state at the logical value of “0” before a timing at which the laser diode is turned into the ON state at the logical value of “1”. Further, JP2018-1523A discloses that a wiring for supplying a bias voltage for retaining the laser diode in the ON state at the logical value of “0” is provided.

JP2015-217674A discloses an image forming apparatus. In this case, a scanning period is configured by an image period and a non-image period. The image forming apparatus determines a switching current at an early stage by temporarily transitioning to a VDO mode in which an image is able to be formed even in the non-image period.

### SUMMARY

Since the thyristor has a capacitance, the transmission of a signal from the gate electrode to the thyristor may be delayed, and the light emission of a light emitting element may be delayed. In this case, the amount of light emitted for a time in which the light emission is delayed is reduced. Thus, it is required to perform control so that the light emission of the light emitting element is less likely to be delayed.

Aspects of non-limiting embodiments of the present disclosure relate to a light emitting device and a measurement apparatus capable of controlling a light emitting element so that light emission is less likely to be delayed.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting device including: a light emitting unit that includes a light emitting element having a function of a thyristor; and a drive unit that performs, before a period in which light emitted from the light emitting unit is used, control such that a predetermined current or larger flows in the thyristor of the light emitting unit.

### BRIEF DESCRIPTION OF THE DRAWINGS

Exemplary embodiment(s) of the present invention will be described in detail based on the following figures, wherein:

FIG. 1 is a diagram illustrating an example of an information processing apparatus;

FIG. 2 is a block diagram illustrating a configuration of the information processing apparatus;

FIG. 3 is a perspective view illustrating a state in which a light source of a light emitting device irradiates an irradiation region in a divided manner;

FIG. 4 is a diagram illustrating the light source in the light emitting device;

FIG. 5 is a diagram illustrating an arrangement of the light source and a drive unit in the light emitting device;

FIG. 6 illustrates an equivalent circuit of the light emitting device to which the present exemplary embodiment is applied;

FIG. 7 is a timing chart illustrating an operation of the light emitting device;

FIGS. 8A and 8B are diagrams illustrating a current flowing in a light emitting unit;

FIGS. 9A and 9B are diagrams illustrating a phenomenon that occurs in a case where a charging current does not flow; FIGS. 10A and 10B are diagrams illustrating a comparison of a difference in an amount of emitted light between a case where the charging current has flowed in advance and a case where the charging current does not flow; (a) and (b) of FIG. 11 are diagrams illustrating a delay in light emission;

FIG. 12 is a diagram illustrating an effect in a case where the charging current is applied; (a) to (d) of FIG. 13 are diagrams illustrating the effect in a case where the charging current is applied;

FIG. 14 is an enlarged plan view illustrating the light emitting unit; and

FIGS. 15A and 15B are cross-sectional views illustrating the light emitting unit, in which FIG. 15A is a cross-sectional view taken along line XVA-XVA in FIG. 14, and FIG. 15B is a cross-sectional view taken along line XVB-XVB in FIG. 14.

### DETAILED DESCRIPTION

Hereinafter, exemplary embodiments of the present invention will be described in detail with reference to the accompanying drawings.

As a measurement apparatus that measures a three-dimensional shape (referred to as a 3D shape below) of a measurement target object, there is an apparatus that measures the three-dimensional shape based on a so-called time-of-flight (ToF) method using the flight time of light. In the ToF method, a time from a timing at which light from a light emitting device provided in the measurement apparatus is radiated to a timing at which the radiated light is reflected by the measurement target object and received by a three-dimensional sensor (referred to as a 3D sensor below) provided in the measurement apparatus is measured. The 3D shape of the measurement target object is specified from the measured time. A target for measuring the 3D shape is referred to as the measurement target object. A three-dimensional shape may be referred to as a three-dimensional image. Further, measuring a three-dimensional shape may be referred to as three-dimensional measurement, 3D measurement, or 3D sensing.

Such a measurement apparatus is applied to recognize the measurement target object from the measured 3D shape. For example, the measurement apparatus is mounted in a portable information processing apparatus or the like and is used for recognizing the face of a user who attempts to access the information processing apparatus. That is, the measurement apparatus acquires the 3D shape of the face of the accessing user, and identifies whether or not the access is permitted. Only in a case where it is recognized that the user is permitted to access the information processing apparatus, using the own apparatus (portable information processing apparatus) is permitted.

Further, the measurement apparatus is also applied to a case of continuously measuring the 3D shape of a measurement target object, such as augmented reality (AR). In this case, the distance to the measurement target object does not matter.

Such a measurement apparatus may be applied to an information processing apparatus such as a personal computer (PC) other than the portable information processing apparatus.

Here, description will be made on the assumption that a portable information processing apparatus is provided as an example of the information processing apparatus, and the information processing apparatus recognizes the face captured as a 3D shape to authenticate a user.

### Information Processing Apparatus 1

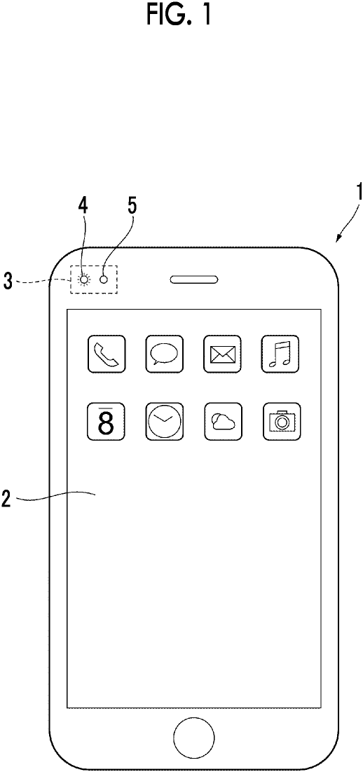

FIG. 1 is a diagram illustrating an example of an information processing apparatus 1. As described above, the information processing apparatus 1 is a portable information processing apparatus as an example.

The information processing apparatus 1 includes a user interface unit (referred to as a UI unit below) 2 and an optical device 3 that measures a 3D shape. In the UI unit 2, for example, a display device that displays information to a user and an input device to which an instruction for information processing by an operation of the user is input are integrated. The display device is, for example, a liquid crystal display or an organic EL display. The input device is, for example, a touch panel.

The optical device 3 includes a light emitting device 4 and a 3D sensor 5. The light emitting device 4 irradiates a measurement target object, in this example, the face, with light. The 3D sensor 5 acquires the light that has been reflected by the face and then returned. Here, a 3D shape is measured based on the so-called ToF method using the flight time of light. The face is recognized from the 3D shape. As described above, the 3D shape may be measured by using an object other than the face as the measurement target object. That is, the 3D sensor 5 functions as a light receiving unit that receives reflected light from the measurement target object irradiated with light from the light emitting device 4. The measurement apparatus that measures the 3D shape includes the light emitting device 4 and the 3D sensor 5.

The information processing apparatus 1 is a computer including a CPU, a ROM, a RAM, and the like. The ROM includes a non-volatile rewritable memory, for example, a flash memory. Programs and constants stored in the ROM are loaded into the RAM, and the CPU executes the program, and thus the information processing apparatus 1 operates and various types of information processing are performed.

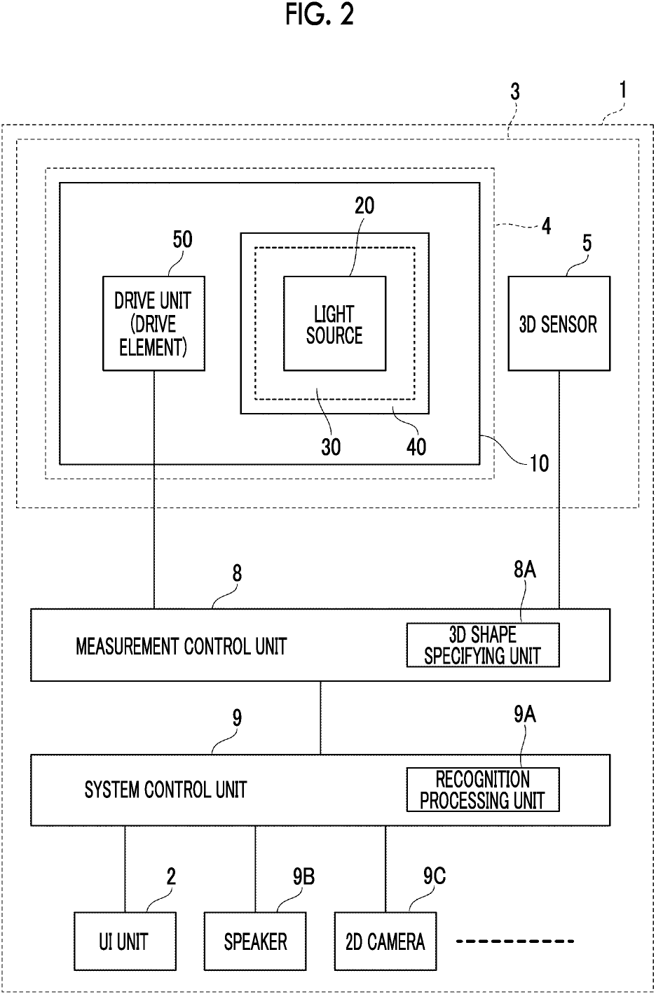

FIG. 2 is a block diagram illustrating a configuration of the information processing apparatus 1.

The information processing apparatus 1 includes the above-described optical device 3, a measurement control unit 8, and a system control unit 9. The measurement control unit 8 controls the optical device 3 to measure a 3D shape. The measurement control unit 8 functions as a processing unit that processes information regarding light received by the 3D sensor 5 to measure a distance from the light emitting device 4 to the measurement target object or the shape of the measurement target object. The measurement control unit 8 includes a 3D shape specifying unit 8A. The system control unit 9 controls the entirety of the information processing apparatus 1 as a system. The system control unit 9 includes a recognition processing unit 9A. The UI unit 2, a speaker 9B, a two-dimensional camera (referred to as a 2D camera in FIG. 2) 9C, and the like are connected to the system control unit 9.

The 3D shape specifying unit 8A provided in the measurement control unit 8 measures a 3D shape from the reflected light from the measurement target object, and specifies the 3D shape of the measurement target object. The recognition processing unit 9A provided in the system control unit 9 recognizes the measurement target object, in this example, the face from the 3D shape specified by the 3D shape specifying unit 8A. Based on the recognized face, it is identified whether or not the user is permitted to access the information processing apparatus.

The light emitting device 4 provided in the optical device 3 includes a wiring substrate 10, a light source 20, a light diffusion member 30, and a drive unit 50. The light source 20 and the drive unit 50 are disposed on the wiring substrate 10. The light source 20 and the drive unit 50 are connected to each other by a wiring provided on the wiring substrate 10. The drive unit 50 supplies a current for light emission to the light source 20. The light diffusion member 30 is inserted into the path of light radiated by the light source 20 and causes irradiation with light radiated by the light source 20 to be performed in a direction in which irradiation is intended. For example, the light diffusion member 30 is held by a holding portion 40 provided on the wiring substrate 10 and covers the light source 20. The wiring substrate 10 may include a resistive element or a capacitive element in order to operate the light source 20 and the drive unit 50. Further, the light source 20 may be provided on a heat dissipation base material having a higher thermal conductivity than the thermal conductivity of the wiring substrate 10. Examples of the heat dissipation base material include aluminum oxide (AI₂O₃) having a thermal conductivity of 20 to 30 W/m·K, silicon nitride (Si₃N₄) having a thermal conductivity of about 85 W/m·K, or aluminum nitride (AlN) having a thermal conductivity of 150 to 250 W/m·K, in comparison to a case where the thermal conductivity of an insulating layer that is used for the wiring substrate 10 and is called FR-4 is about 0.4 W/m·K. Although it is assumed that the wiring is provided on the wiring substrate 10, the wiring substrate 10 may be a substrate on which the wiring is not provided. The light source 20 and the drive unit 50 may be connected to each other, and the substrate may be any one that holds the light source 20, the drive unit 50, and the like.

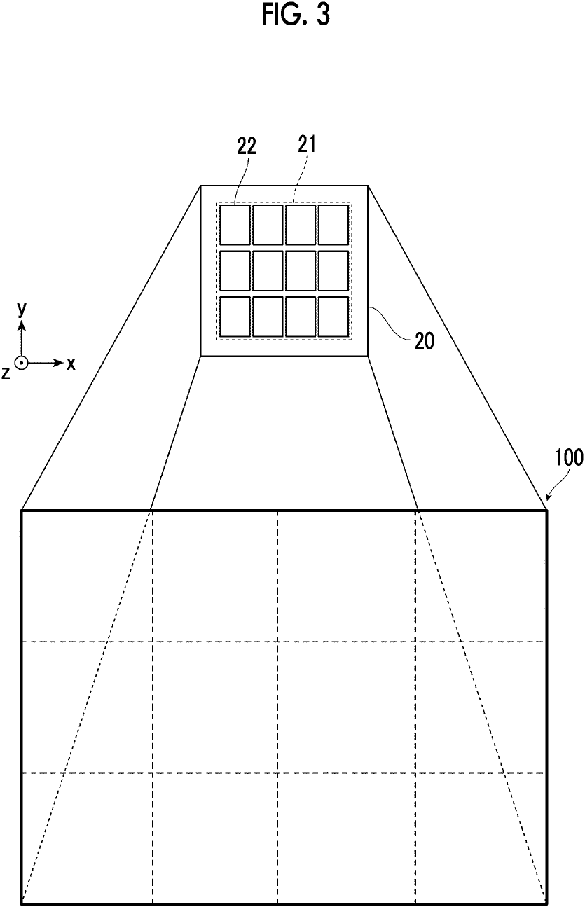

FIG. 3 is a perspective view illustrating a state in which the light source 20 of the light emitting device 4 irradiates an irradiation region 100 in a divided manner. FIG. 3 illustrates the light source 20 of the light emitting device 4. In FIG. 3, in the portion of the light source 20, the right direction of the surface of paper is defined as an x-direction, the upward direction of the surface of the paper is defined as a y-direction, and a direction toward the irradiation region 100 is defined as a z-direction.

The light source 20 includes 12 light emitting units 22 as an example. The 12 light emitting units 22 are collectively referred to as a light radiation unit 21. The 12 light emitting units 22 are arranged in a matrix of four in the x-direction and three in the y-direction. Each of the light emitting units 22 may emit light individually, or a plurality of light emitting units 22 may simultaneously emit light. Further, all of the light emitting units 22 may simultaneously emit light.

The irradiation region 100 refers to a range in which irradiation with the light radiated by the light source 20 is performed in order to measure the 3D shape of a measurement target object. Here, each of the light emitting units 22 has a different irradiation range. That is, the light source 20 divides the irradiation region 100 and then performs irradiation. The light radiated by the light emitting unit 22 passes through the light diffusion member 30 (see FIG. 2), and thus a direction in which irradiation with the light is performed and/or the spread of the light is set. An optical member such as a diffractive optical element (DOE) that radiates incident light while changing the direction of the incident light to a different direction, and a transparent member such as a condensing lens, a microlens, and a protective cover may be provided instead of the light diffusion member 30.

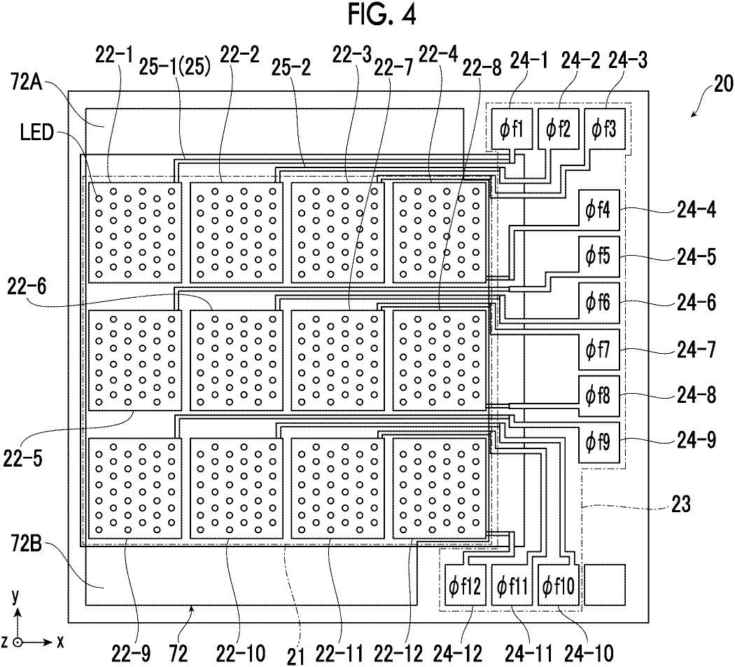

FIG. 4 is a diagram illustrating the light source 20 in the light emitting device 4. An x-direction, a y-direction, and a z-direction in FIG. 4 are identical to the directions in FIG. 3.

The light source 20 includes a light radiation unit 21 in which a plurality of light emitting units 22 are arranged, a switching unit 23 that switches the light emitting unit 22 that emits light, and a wiring 25 for connecting the light emitting unit 22 and the switching unit 23.

As described above, the light radiation unit 21 includes 12 light emitting units 22 arranged in a matrix of four in the x-direction and three in the y-direction. Here, in order to distinguish the light emitting units 22 from each other, the light emitting units 22 are referred to as light emitting units 22-1 to 22-12. The circles marked on the light emitting unit 22 are light emitting diodes LED. That is, each light emitting unit 22 includes a plurality of light emitting diodes LED. The plurality of light emitting diodes LED are an example of a light-emitting-element group in which a plurality of light emitting elements emit light together. The plurality of light emitting diodes LED have a structure of being arranged in a form of a plurality of surfaces. Further, the drive unit 50 controls light emission for each of the plurality of light emitting diodes LED.

Each light emitting unit 22 may include the identical number of light emitting elements, or may include a different number of light emitting elements. The number of light emitting elements provided in the light emitting unit 22 may be one.

A light emission electrode 72 is provided in common to all the light emitting units 22, over the light emitting unit 22 (on the z-direction side). The ± y direction sides of the light emission electrode 72 function as pad portions 72A and 72B to which wirings for supplying a light emitting current are connected. Regarding the light emission electrode 72, only the frame is illustrated so that the light emitting unit 22 under the light emission electrode 72 can be seen.

The switching unit 23 includes signal terminals 24-1 to 24-12 for supplying switching signals φf1 to φf12 to the respective light emitting units 22-1 to 22-12. In a case where the switching signals φf1 to φf12 are not distinguished from each other, the switching signals φf1 to φf12 are referred to as switching signals φf. In a case where the signal terminals 24-1 to 24-12 are not distinguished from each other, the signal terminals 24-1 to 24-12 are referred to as signal terminals 24. The switching units 23 are collectively arranged on the x-direction side of the light radiation unit 21 including the plurality of light emitting units 22. In the switching units 23, the signal terminals 24 may be arranged in one row on the y-direction side. With such an arrangement, the length in the x-direction is shorter than the length in a case where the signal terminals 24 are not arranged in one row.

The light emitting unit 22 of the light radiation unit 21 and the signal terminal 24 of the switching unit 23 are connected to each other by the wiring 25, and the switching signal φf is supplied from the signal terminal 24. That is, the light emitting unit 22-1 and the signal terminal 24-1 are connected to each other by a wiring 25-1, and the switching signal φf1 is supplied. The light emitting unit 22-2 and the signal terminal 24-2 are connected to each other by a wiring 25-2, and the switching signal φf2 is supplied from the signal terminal 24-2. In FIG. 4, the wirings 25-1 and 25-2 are illustrated, and illustrations of other wirings 25-3 to 25-12 are omitted.

The wiring 25 is provided along the light emitting unit 22 on the outside of the light emitting unit 22. Thus, the light emitting diodes LED are provided at a higher density than a density in a case where the wiring is provided inside the light emitting unit 22, that is, on the surface. Further, in FIG. 4, a region including the light radiation unit 21 and the switching unit 23 has a length in the x-direction, which is longer than the length in the y-direction.

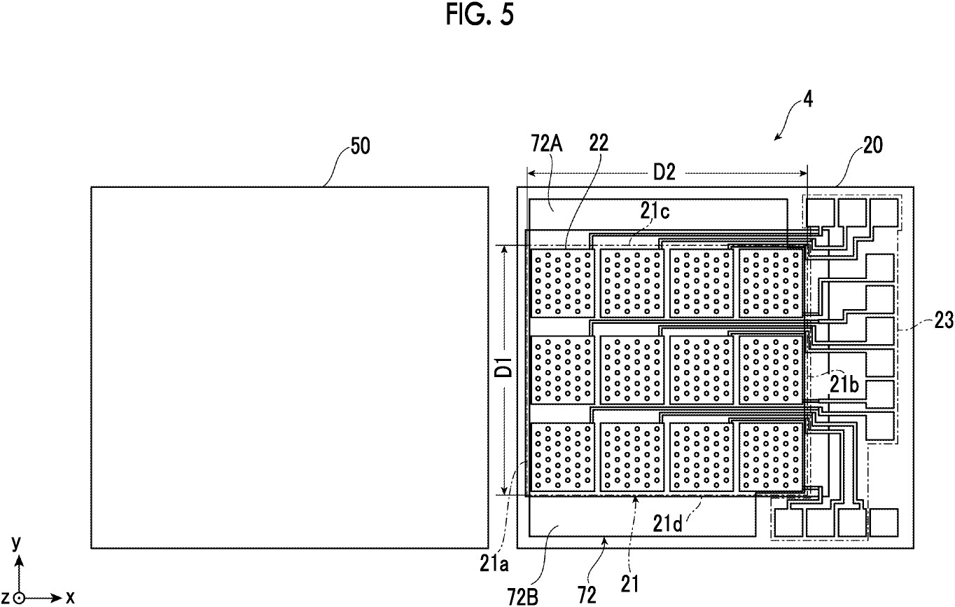

FIG. 5 is a diagram illustrating an arrangement of the light source 20 and the drive unit 50 in the light emitting device 4. An x-direction, a y-direction, and a z-direction in FIG. 5 are identical to the directions in FIG. 4.

Here, the -x direction side of the light radiation unit 21 including the plurality of light emitting units 22 is referred to as an edge 21a, the +x direction side of such a light radiation unit 21 is referred to as an edge 21b, the +y direction side of such a light radiation unit 21 is referred to as an edge 21c, and the -y direction side of such a light radiation unit 21 is referred to as an edge 21d. The edge 21a and the edge 21b face each other. The edge 21c and the edge 21d face each other while connecting the edge 21a and the edge 21b to each other. That is, the plurality of light emitting units 22 of the light radiation unit 21 are surrounded by the edges 21a, 21b, 21c, and 21d. The edge 21a has a length D1, and the edge 21c has a length D2. Here, the length D1 is set to be shorter than the length D2 (D1 < D2). Here, the edge 21a is an example of a first edge, the edge 21b is an example of a second edge, the edge 21c is an example of a third edge, and the edge 21d is an example of a fourth edge.

As illustrated in FIG. 5, the switching units 23 are arranged at a position opposite to the drive unit 50. That is, the drive unit 50 is provided adjacent to the light emitting unit 22 side of the light radiation unit 21. That is, the drive unit 50 is provided on the edge 21a side of the light radiation unit 21, and the switching units 23 are provided on the edge 21b side of the light radiation unit 21. That is, the drive unit 50 and the switching units 23 are provided on the edge sides facing each other. Thus, the distance between the drive unit 50 and the light emitting unit 22 is shorter than the distance in a case where the switching units 23 are provided at positions between the drive unit 50 and the light emitting unit 22. Thus, in the light emitting device 4, the inductance between the drive unit 50 and the light emitting unit 22 in the light source 20 is reduced, and the rising time of an optical pulse is reduced. Further, since the 3D sensor 5 is disposed at the position illustrated in FIG. 1, the 3D sensor 5 is provided on the switching unit 23 side. That is, the drive unit 50, the light emitting units 22, the switching units 23, and the 3D sensor 5 are arranged in this order.

Further, in the light emission electrode 72, the pad portion 72A is provided on the edge 21c side of the light radiation unit 21 including the light emitting unit 22, and the pad portion 72B is provided on the edge 21d side of the light radiation unit 21. That is, the pad portions 72A and 72B are provided outside the light radiation unit 21 at positions different from the positions where the drive unit 50 and the switching unit 23 are provided, with respect to the light radiation unit 21. In a case where the pad portions 72A and 72B are provided at positions where the switching unit 23 or the drive unit 50 is provided, the connection to the pad portions 72A and 72B may be hindered by the switching unit 23 or the drive unit 50. That is, it is possible to facilitate the connection to the pad portions 72A and 72B in comparison to a case where the pad portions 72A and 72B are provided at the positions where the switching unit 23 or the drive unit 50 is provided. The pad portions 72A and 72B are provided at both the edges 21c and 21d. Thus, a current is supplied from both sides of the light emission electrode 72. As a result, the bias of the current supply to the light emitting unit 22 is suppressed in comparison to a case where the pad portion is provided on either the edge 21c or the edge 21d.

That is, the drive unit 50, the switching units 23, and the light emission electrode 72 are provided on different edge sides of the light radiation unit 21. As a result, it is possible to reduce the planar shape of the light emitting device 4.

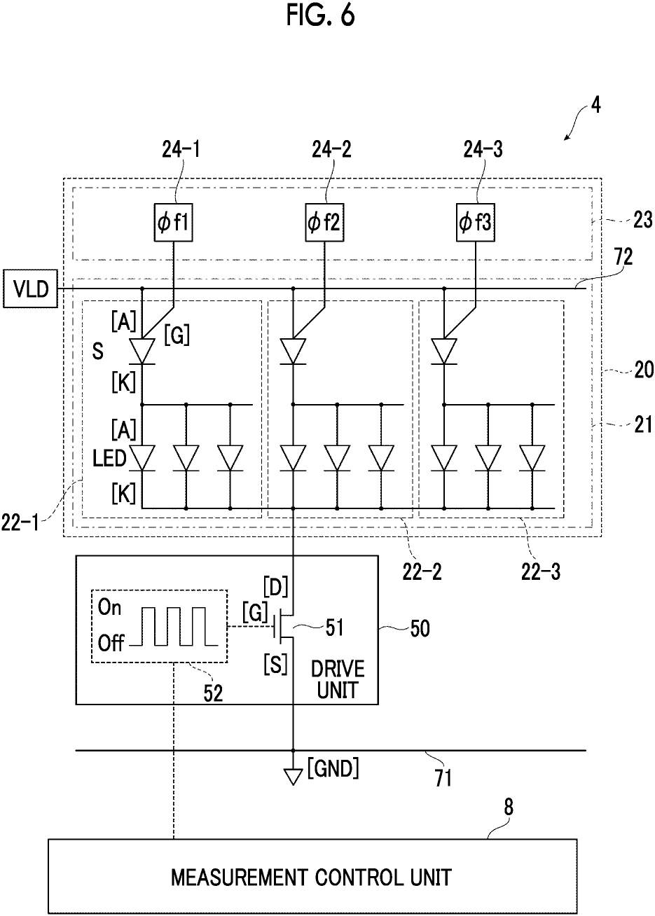

FIG. 6 illustrates an equivalent circuit of the light emitting device 4 to which the present exemplary embodiment is applied. FIG. 6 illustrates the light source 20 and the drive unit 50 in the light emitting device 4. FIG. 6 also illustrates the measurement control unit 8 that controls the light emitting device 4.

As described above, the light source 20 includes the light radiation unit 21 and the switching unit 23 that switches a plurality of light emitting units 22 in the light radiation unit 21. FIG. 6 illustrates three light emitting units 22 (denoted as light emitting units 22-1, 22-2, and 22-3). As described with the light emitting unit 22-1, each light emitting unit 22 includes a plurality of light emitting diodes LED. Each light emitting unit 22 includes a drive thyristor S that is commonly connected to the plurality of light emitting diodes LED. This can also mean that the light emitting diode LED has the function of a thyristor.

The light emitting diode LED is, for example, a vertical cavity surface emitting laser (VCSEL). In the present exemplary embodiment, the light emitting diode LED is set as a light emitting element that emits light by being driven under a condition of actively generating relaxation oscillation. That is, the light emitting diode LED is set as a light emitting element that emits light by relaxation oscillation. In a case where the relaxation oscillation is largely generated, the initial light emission output may be large, but the subsequent output may be reduced, and an unstable waveform may be obtained. In addition, the relaxation oscillation may be adjusted to be small. The vertical cavity surface emitting laser VCSEL is a surface emitting laser element in which a light emitting layer functioning as a light emitting region is provided between a lower multilayer-film reflecting mirror and an upper multilayer-film reflecting mirror that are stacked on a substrate, and laser light is radiated in a direction perpendicular to the surface. The vertical cavity surface emitting laser VCSEL here has a λ resonator structure. The light emitting element may be another light emitting device such as a laser diode other than the vertical cavity surface emitting laser VCSEL. The vertical cavity surface emitting laser VCSEL may be referred to as a VCSEL below.

The drive unit 50 includes a MOS transistor 51 and a signal generation circuit 52. As the MOS transistor, an insulated gate bipolar transistor (IGBT) or the like may be provided.

The plurality of light emitting diodes LED and the drive thyristor S are connected in series. That is, the plurality of light emitting diodes LED are connected in parallel, and the anode ([A]) of the light emitting diode LED is connected to the cathode ([K]) of the drive thyristor S. Similarly, the cathode ([K]) of the light emitting diode LED is connected in parallel and connected to the drain ( [D] ) of the MOS transistor 51 in the drive unit 50. The source ([S]) of the MOS transistor 51 is connected to a reference potential wiring 71 for supplying a reference potential GND (0 V).

The anode ([A]) of the drive thyristor S is connected to the light emission electrode 72 to which a power supply potential VLD is supplied. The gate ([G]) of the drive thyristor S is connected to the signal terminal 24 of the switching unit 23. That is, in the light emitting unit 22-1, the gate ([G]) of the drive thyristor S is connected to the signal terminal 24-1, and the switching signal φf1 is supplied. The above description is similarly applied to the other light emitting units 22.

The signal generation circuit 52 in the drive unit 50 supplies an On signal (On) for turning on the MOS transistor 51 and an Off signal (Off) for turning off the MOS transistor 51, to the gate ([G]) of the MOS transistor 51.

A driving method of the light emitting device 4 is so-called low-side driving. For example, in a case where the light emitting diode LED is intended to be driven at a higher speed, low-side driving may be performed. The low-side driving refers to a configuration in which a drive element such as the MOS transistor 51 is positioned on the downstream side of a current path with respect to a drive target such as the light emitting diode LED.

The operation of the light emitting device 4 will be described below.

### Drive Thyristor S

The drive thyristor S is a semiconductor element having three terminals of the anode ([A]), the cathode ([K]), and the gate ([G]). As will be described later, the drive thyristor S is configured by stacking an n-cathode layer 85, a p-gate layer 86, an n-gate layer 87, and a p-anode layer 88 made of GaAs, AlGaAs, AlAs, or the like. That is, the drive thyristor S has an npnp structure. Description will be made by using an example in which the forward voltage (diffusion potential) Vd at a pn junction between the p-type semiconductor layer (p-gate layer 86 and p-anode layer 88) and the n-type semiconductor layer (n-cathode layer 85 and n-gate layer 87) is 1.5 V.

In the drive thyristor S, the gate ([G]) is provided in the n-gate layer 87. First, it is assumed that a voltage is applied between the anode ([A]) and the cathode ([K]) of the drive thyristor S, but the drive thyristor is in the OFF state in which no current flows. In a case where a forward bias occurs between the p-anode layer 88 being the anode ([A]) and the n-gate layer 87 being the gate ([G]), the drive thyristor S transitions to the ON state in which a current flows. That is, in FIG. 6, in a case where the gate ([G]) has a voltage that is lower than the potential of the anode ([A]) by a forward voltage Vd or more, the drive thyristor S transitions from the OFF state to the ON state. The forward voltage Vd is formed between the anode ([A]) and the cathode ([K]). For example, in a case where the anode ([A]) is 5 V, and the gate ([G]) is less than 3.5 V, the drive thyristor S transitions from the OFF state to the ON state. Further, in a case where the anode ([A]) is 10 V, and the gate ([G]) is less than 8.5 V, the drive thyristor S transitions from the OFF state to the ON state.

The gate ([G]) is connected to the signal terminal 24, and the switching signal φf is supplied to the signal terminal 24. That is, the transition from the OFF state to the ON state of the drive thyristor S is controlled by the switching signal φf.

### Light Emitting Diode LED

The light emitting diode LED is a semiconductor element having two terminals of the anode ([A]) and the cathode ([K]). Thus, the light emitting diode LED emits light in a case where a voltage larger than the forward voltage Vd is applied between the anode ([A]) and the cathode ([K]) and a current allowing emission of light flows.

### Operation of Light Emitting Unit 22

As illustrated in FIG. 6, in the light emitting unit 22, the drive thyristor S and the light emitting diode LED are connected in series. The power supply potential VLD is applied to the light emission electrode 72 to which the anode ([A]) of the drive thyristor S is connected. The cathode ([K]) of the light emitting diode LED is connected to the drain ([D]) of the MOS transistor 51 in the drive unit 50. The reference potential GND (0 V) is supplied to the source ([S]) of the MOS transistor 51 in the drive unit 50. The reference potential GND is the ground potential.

Here, it is assumed that the On signal is input from the signal generation circuit 52 to the gate ( [G] ) of the MOS transistor 51, and thus the MOS transistor 51 is turned on. In a case where the MOS transistor 51 is turned on, the cathode ([K]) of the light emitting diode LED in the light emitting unit 22 becomes 0 V. Thus, the power supply potential VLD is applied to the light emitting unit 22.

It is assumed that the power supply potential VLD is 5 V. It is assumed that the switching signal φf has 5 V and the drive thyristor S is in the OFF state. Here, the switching signal φf transitions to a voltage which is lower than the power supply potential VLD of the anode ([A]) of the drive thyristor S by the forward voltage Vd or more, that is, less than 3.5 V. In a case where the switching signal transitions, the drive thyristor S transitions from the OFF state to the ON state. Then, a current flows from the drive thyristor S to the light emitting diode LED. The cathode ([K]) of the drive thyristor S becomes 3.5 V. Therefore, the voltage between the anode ([A]) and the cathode ([K]) of the light emitting diode LED is equal to or more than the forward voltage Vd, and thus the light emitting diode LED emits light.

Further, it is assumed that the power supply potential VLD is 10 V. It is assumed that the switching signal φf has 10 V and the drive thyristor S is in the OFF state. Here, the switching signal φf transitions to a voltage which is lower than the power supply potential VLD being the potential of the anode ([A]) of the drive thyristor S by the forward voltage Vd or more, that is, less than 8.5 V. In a case where the switching signal transitions, the drive thyristor S transitions from the OFF state to the ON state. Then, the current flows from the drive thyristor S to the light emitting diode LED. The cathode ([K]) of the drive thyristor S becomes 8.5 V. Thus, the voltage between the anode ([A]) and the cathode ([K]) of the light emitting diode LED is equal to or more than the forward voltage Vd, and thus the light emitting diode LED emits light.

As described above, the drive thyristor S retains to be in the OFF state in a case where the voltage applied to the gate ([G]), that is, the switching signal φf has a value which is equal to or more than a value obtained by subtracting the forward voltage Vd from the power supply potential VLD. In a case where the switching signal φf becomes less than the value obtained by subtracting the forward voltage Vd from the power supply potential VLD, the drive thyristor S transitions from the OFF state to the ON state.

In a case where the Off signal is input from the signal generation circuit 52 to the gate ([G]) of the MOS transistor 51, the MOS transistor 51 transitions from the ON state to the OFF state. In a case where the MOS transistor 51 transitions, no current flows in the light emitting unit 22, and the light emitting diode LED transitions from the ON state to the OFF state. The drive thyristor S in the ON state does not transition to the OFF state even though the voltage of the gate ([G]) is set to a value or more obtained by subtracting the forward voltage Vd from the power supply potential VLD.

### Timing Chart of Light Emitting Device 4

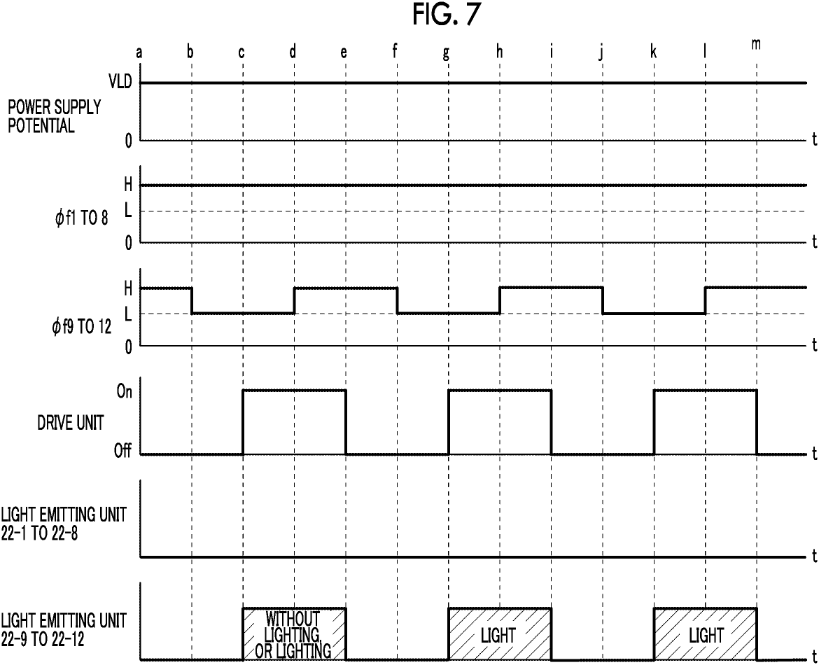

FIG. 7 is a timing chart illustrating the operation of the light emitting device 4. It is assumed that, a time t elapses on the horizontal axis in order of time points a to m. FIG. 7 illustrates, from the top, the power supply potential VLD, the switching signals φf1 to φf8, the switching signals φf9 to φf12, the signal of the signal generation circuit 52 in the drive unit 50, the states of the light emitting units 22-1 to 22-8, and the states of the light emitting units 22-9 to 22-12. The switching signals φf1 to φf12 are signals that are switchable between an H level and an L level. The H level is equal to or higher than the value obtained by subtracting the forward voltage Vd from the power supply potential VLD. The L level is lower than the value obtained by subtracting the forward voltage Vd from the power supply potential VLD. Here, as an example, it is assumed that the switching signals φf1 to φf8 are retained at the identical potential, and the switching signals φf9 to φf12 are simultaneously switched. The switching signals φf1 to φf12 may be individually switched, or a plurality of switching signals may be simultaneously switched as described above. Further, all the switching signals φf1 to φf12 may be simultaneously switched.

At the time point a, the light emitting units 22-1 to 22-12 are in the OFF state. The switching signals φf1 to φf12 are at the H level. The signal generation circuit 52 of the drive unit 50 supplies the Off signal to the MOS transistor 51. Thus, all the drive thyristors S are in the OFF state, and all the light emitting diodes LED are in a non-light emission state.

At a time point b, the switching signals cpf9 to φf12 transition from the H level to the L level. In a case where the switching signals transition, the gate ([G]) of the drive thyristors S of the light emitting units 22-9 to 22-12 becomes the L level, and the drive thyristors S turns into a state where transition from the OFF state to the ON state is possible. Since the MOS transistor 51 of the drive unit 50 is in the OFF state, it is not possible for the drive thyristor S to transition to the ON state.

At a time point c, the signal generation circuit 52 of the drive unit 50 supplies the On signal to the MOS transistor 51. In a case where the signal generation circuit 52 supplies the On signal, the power supply potential VLD is applied to the series connection of the drive thyristors S and the light emitting diodes LED in the light emitting units 22-9 to 22-12. At this time, as will be described in detail later, a predetermined current flows. In this case, depending on the current value, the light emitting diode LED may turn into the non-light emission state without starting (lighting) light emission, or may start light emission (lighting). Even in the non-light emission state, for example, it is preferable that the drive thyristor S transitions from the OFF state to the ON state. Even in this case, the non-light emission state is caused by setting the flowing current to be less than a threshold current of the light emitting diode LED. In a case where the light emission is started (lit), the drive thyristor S transitions from the OFF state to the ON state, and the flowing current is set to be equal to or higher than the threshold current for causing the light emitting diode LED to emit light.

At a time point d, the switching signals cpf9 to φf12 transition from the L level to the H level. In a case where the light emitting diode LED is lit at the time point c, the drive thyristors S of the light emitting units 22-9 to 22-12 do not transition to the OFF state, and the light emitting diode LED continues to emit light.

At a time point e, the signal generation circuit 52 of the drive unit 50 supplies the Off signal to the MOS transistor 51. In a case where the light emitting diode LED is lit at the time point c, no current flows in the series connection between the drive thyristors S and the light emitting diodes LED in the light emitting units 22-9 to 22-12, and thus the light emitting diode LED stops (turns off) light emission.

The state at a time point f is similar to the state at the time point b. That is, the switching signals cpf9 to φf12 transition from the H level to the L level. In a case where the switching signals transition, the gate ([G]) of the drive thyristors S of the light emitting units 22-9 to 22-12 becomes the L level, and the drive thyristors S turns into a state where transition from the OFF state to the ON state is possible. Since the MOS transistor 51 of the drive unit 50 is in the OFF state, it is not possible for the drive thyristor S to transition to the ON state.

At a time point g, the signal generation circuit 52 of the drive unit 50 supplies the On signal to the MOS transistor 51. In a case where the signal generation circuit 52 supplies the On signal, the power supply potential VLD is applied to the series connection of the drive thyristors S and the light emitting diodes LED in the light emitting units 22-9 to 22-12. Thus, the drive thyristor S transitions from the OFF state to the ON state, and the light emitting diode LED starts (lights) light emission.

At a time point h, the switching signals cpf9 to φf12 transition from the L level to the H level. However, the drive thyristors S of the light emitting units 22-9 to 22-12 do not transition to the OFF state, and the light emitting diodes LED continue to emit light.

At a time point i, the signal generation circuit 52 of the drive unit 50 supplies the Off signal to the MOS transistor 51. In a case where the signal generation circuit 52 supplies the Off signal, no current flows in the series connection between the drive thyristors S and the light emitting diodes LED in the light emitting units 22-9 to 22-12, and thus the light emitting diodes LED stop (turn off) light emission.

States at a time point j, a time point k, a time point 1, and a time point m are similar to the states at the time point f, the time point g, the time point h, and the time point i, respectively. That is, the light emitting diode LED is in a light emission state during a period between the time point k and the time point m. The example in which the switching signals cpf9 to φf12 transition from the L level to the H level at the time point d has been described, but the L level may be retained until the time point m. In addition, depending on the capacitance of the light emitting element, the switching signals may transition from the L level to the H level at the time point d, and then may continuously be retained at the H level.

In this case, the drive unit 50 may perform control such that the current flows so that the light emitting unit 22 emits light a plurality of times.

In the present exemplary embodiment, the light emitted from the light emitting diode LED is used for three-dimensional measurement in a time section after the time point g. The drive unit 50 performs control such that a predetermined current or larger flows in the drive thyristor S of the light emitting unit 22, before a period in which the light emitted from the light emitting unit 22 is used (after the time point g) . In this case, the “period in which the light emitted from the light emitting unit 22 is used” is a period in which the information processing apparatus 1 performs three-dimensional measurement using the light emitted from the light emitting unit 22. That is, such a period is a period from the start to the end of the three-dimensional measurement, and is a period after the time point g. Further, a period before such a period is a period before the start of the three-dimensional measurement by the information processing apparatus 1, and is a period after the time point a and before the time point g. Light reception of the 3D sensor 5 may not be performed during the period before using the light. Regarding calculation of the three-dimensional measurement, even though the 3D sensor 5 does not receive light, for example, the calculation may be performed by excluding reflected light of the light before the period in which the light is used. For example, the measurement control unit 8 (see FIG. 2) performs such processing. In this case, the measurement control unit 8 functions as a control unit that prevents first emitted light among rays of the light emitted from the light emitting unit 22 from being used as the light reception result of the light receiving unit 22.

It is not necessary to completely prohibit the use of the light for a period before using the light. For example, considering the inside of each block B described later, it is expected that the output is not stable, for example, due to uneven light emission in the block B during this period. Even though the intended light emission is not obtained, there is no limit on the use of sufficient light emission, for example, only a check of whether or not there is an output at one light emitting point in the block B.

The predetermined current or larger flowing in the drive thyristor S will be described separately for a case where the light emitting unit 22 is not lit, and a case where the light emitting unit 22 is lit.

### Case Where Light Emitting Unit 22 Is Not Lit

In a case where the light emitting unit 22 is not lit at the time point c, the predetermined current is smaller than a current for causing the light emitting unit 22 to emit light, and the drive unit 50 does not cause the light emitting diode LED to emit light. In particular, in the present exemplary embodiment, the light emitting element that emits light by relaxation oscillation is used. Thus, the predetermined current is set to a current small enough to not only cause the light emitting unit 22 not to emit light, but also cause the light emitting element to emit light by actively utilizing the relaxation oscillation even after the predetermined current flows. Description will be made below on the assumption that the light emitting diode LED is a vertical cavity surface emitting laser VCSEL.

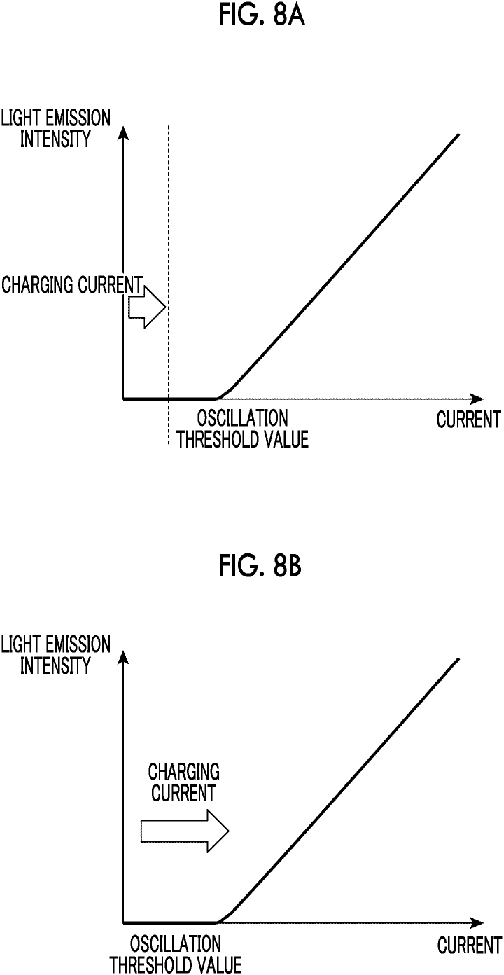

FIG. 8A is a diagram illustrating a current flowing in the light emitting unit 22 at this time. In FIG. 8A, the horizontal axis represents the current flowing in the light emitting unit 22, and the vertical axis represents the light emission intensity of the vertical cavity surface emitting laser VCSEL.

FIG. 8A illustrates the predetermined current as a “charging current”. FIG. 8A illustrates that the charging current is smaller than an oscillation threshold value of the vertical cavity surface emitting laser VCSEL. That is, by such a charging current flowing, the vertical cavity surface emitting laser VCSEL does not oscillate, and does not emit light.

### Case Where Light Emitting Unit 22 Is Lit

In a case where the light emitting unit 22 is lit at the time point c, the predetermined current or larger is a current having a magnitude that allows the light emitting unit 22 to emit light, and the drive unit 50 causes the light emitting diode LED to emit light.

FIG. 8B is a diagram illustrating a current flowing in the light emitting unit 22 at this time. In FIG. 8B, the horizontal axis represents the current flowing in the light emitting unit 22, and the vertical axis represents the light emission intensity of the vertical cavity surface emitting laser VCSEL.

FIG. 8B illustrates that the charging current being the predetermined current is larger than the oscillation threshold value of the vertical cavity surface emitting laser VCSEL. That is, by such a charging current flowing, the vertical cavity surface emitting laser VCSEL oscillates, and emits light. However, the vertical cavity surface emitting laser VCSEL emits light during a period before the information processing apparatus 1 starts the three-dimensional measurement. Therefore, even though the vertical cavity surface emitting laser VCSEL emits light, this does not have an influence on the three-dimensional measurement by the information processing apparatus 1.

For example, it is preferable that the time for the charging current flowing is set to be longer than the time for the current flowing in a case where the vertical cavity surface emitting laser VCSEL is caused to emit light. That is, in the example of FIG. 7, the time for the charging current flowing is the time from the time point c to the time point e. Further, the time for the current flowing in a case where the vertical cavity surface emitting laser VCSEL is caused to emit light is the time from the time point g to the time point i or the time point k to the time point m. Thus, the time from the time point c to the time point e is set to be longer than the time from the time point g to the time point i or the time from the time point k to the time point m. This makes it easier to satisfy the charging current flowing in the drive thyristor S. That is, it is possible to more reliably cause a required amount of current to flow in the drive thyristor S. As a result, the delay in light emission of the vertical cavity surface emitting laser VCSEL is less likely to occur. In the above-described example, the charging current is applied as a pulse, but may be caused to normally flow before the period in which the light emitted from the light emitting unit 22 is used.

Further, as illustrated in FIG. 7, the light emitting unit 22 may be caused to emit light a plurality of times during the period in which the light emitted from the light emitting unit 22 is used, that is, may be made be a pulse. In this case, for example, it is preferable that control is performed so that a time interval from the application of the charging current to the first light emission among a plurality of light emissions and a time interval for each of the plurality of light emissions are aligned. That is, a time interval of the time point e to the time point g and a time interval of the time point i to the time point k are aligned. This simplifies the control of the light emitting unit 22. Further, as a result of easy design of charging and discharging capacitances in the circuit, it is easy to secure a sufficient amount of current to flow in the drive thyristor S.

Further, as illustrated in FIG. 7, in a case where the vertical cavity surface emitting laser VCSEL is caused to emit light, control is performed such that the charging current flows in the drive thyristor S of the vertical cavity surface emitting laser VCSEL. On the other hand, for example, it is preferable that, in a case where the vertical cavity surface emitting laser VCSEL is not caused to emit light, control of the charging current not flowing is performed. That is, in the example of FIG. 7, since the light emitting units 22-9 to 22-12 are caused to emit light, the charging current flows in the light emitting units 22-9 to 22-12. On the other hand, since the light emitting units 22-1 to 22-8 are not caused to emit light, the charging current does not flow in the light emitting units 22-1 to 22-8. This makes it easier to apply a predetermined amount of charging current to the thyristor.

### Detailed Description of Charging Current

Next, the charging current will be described in more detail.

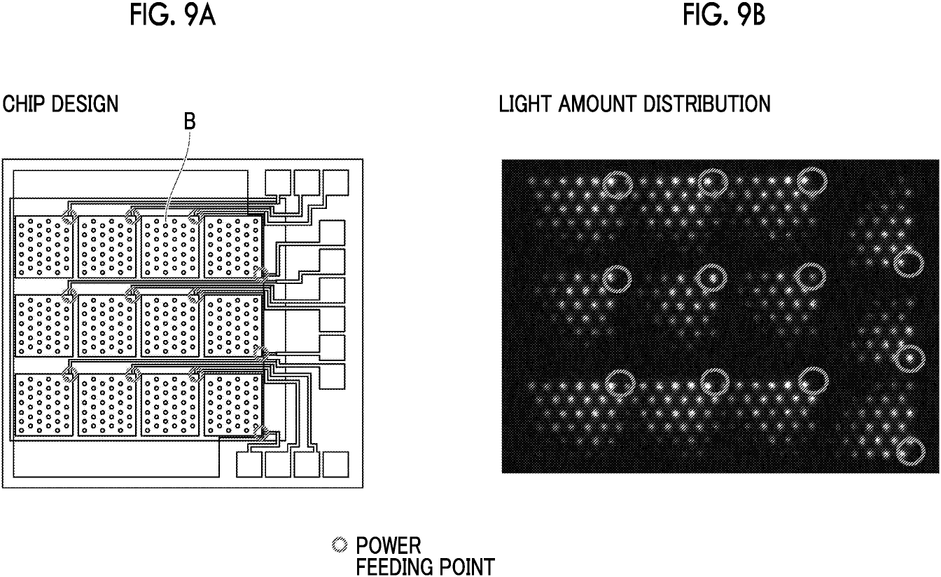

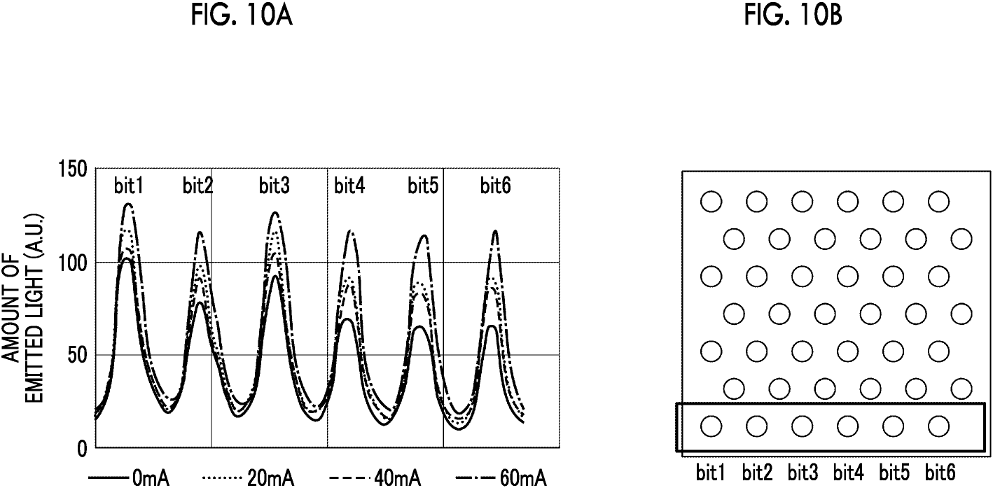

FIGS. 9A and 9B are diagrams illustrating a phenomenon that occurs in a case where the charging current does not flow.

Among FIGS. 9A and 9B, FIG. 9A illustrates the chip design of the vertical cavity surface emitting laser VCSEL, and “o” indicates a power feeding point. Further, FIG. 9B illustrates the light amount distribution of the vertical cavity surface emitting laser VCSEL in a case where no charging current flows. In addition, “o” indicates a power feeding point. FIG. 9B illustrates that the closer to white, the larger the amount of light, and the closer to black, the smaller the amount of light. The power feeding point is common to the plurality of vertical cavity surface emitting lasers VCSEL, and the vertical cavity surface emitting laser VCSEL in each block B separated by the dotted line emits light and turns off in the same manner. Here, the number of blocks B is 12.

As illustrated in FIG. 9B, it can be understood that the amount of light decreases as the distance from the power feeding point indicated by “o” increases. The reason is that the drive thyristor S has a capacitance. That is, since the drive thyristor S has a capacitance, the transmission of a signal from the power feeding point to the vertical cavity surface emitting laser VCSEL is delayed. Therefore, the light emission of the vertical cavity surface emitting laser VCSEL is delayed. As a result, the amount of light emitted for a time in a case where the light emission is delayed decreases. Since the capacitance becomes larger as the distance from the power feeding point increases, the light emission of the vertical cavity surface emitting laser VCSEL is delayed more as the distance from the power feeding point increases. Therefore, the farther from the power feeding point, the smaller the amount of emitted light. This can also mean that the amount of emitted light varies depending on the distance from the power feeding point, or uneven light emission occurs. As described above, in a case where a plurality of vertical cavity surface emitting lasers VCSEL are lit by one power feeding point, there is a case where the distance from one power feeding point to each vertical cavity surface emitting laser VCSEL is long. Thus, such a problem of a light emission delay tends to become more prominent.

Thus, in the present exemplary embodiment, such a problem is fixed by causing the charging current to flow in advance. In this case, even though the drive thyristor S has a capacitance, it is possible to charge the drive thyristor S in advance by applying the charging current, and transmission of a signal from the power feeding point to the vertical cavity surface emitting laser VCSEL is less likely to be delayed. Therefore, the problem of reducing the amount of emitted light as described above is less likely to occur.

FIGS. 10A and 10B are diagrams illustrating a comparison of a difference in the amount of emitted light between a case where the charging current has flowed in advance and a case where the charging current does not flow.

Among FIGS. 10A and 10B, FIG. 10B is a diagram illustrating the vertical cavity surface emitting laser VCSEL in which the amount of emitted light is measured. Here, the amount of emitted light is measured for six vertical cavity surface emitting lasers VCSELs indicated by bit1 to bit6 in the solid rectangle.

Further, FIG. 10A is a diagram illustrating the relationship between the charging current and the amount of emitted light for the six vertical cavity surface emitting lasers VCSELs of bit1 to bit6. Here, the horizontal axis represents the positions of bit1 to bit6, and the vertical axis represents the amount of emitted light. Here, the amount of emitted light in a case where the predetermined charging current is changed to 0 mA, 20 mA, 40 mA, and 60 mA is illustrated. That is, a case where the charging current is 0 mA is similar to a case in the related art and corresponds to a case where the charging current does not flow. Further, the cases of 20 mA, 40 mA, and 60 mA correspond to a case where the present exemplary embodiment is applied, and a case where the predetermined charging current has flowed.

As illustrated in FIGS. 10A and 10B, in comparison to the case of 0 mA in which the charging current does not flow, the amount of emitted light increases and the amount of emitted light is less likely to vary, while the charging current is increased to 20 mA, 40 mA, and 60 mA.

(a) and (b) of FIG. 11 are diagrams illustrating a delay in the light emission.

Among (a) and (b) of FIG. 11, (b) of FIG. 11 is a diagram illustrating the amount of emitted light with time. Here, the horizontal axis represents the time and the vertical axis represents the amount of emitted light. Further, (a) of FIG. 11 illustrates places in which the amount of emitted light has been measured. Here, (a) of FIG. 11 illustrates that the amount of emitted light has been measured at three points of Position 1 to Position 3 indicated by “o” of the thick line. Further, for Position 1, Position 3, and Position 2, the distance from the power feeding point increases in this order.

As illustrated in (b) of FIG. 11, (b) of FIG. 11 illustrates the amount of emitted light with time, for two points of Position 1 and Position 2. As illustrated in (b) of FIG. 11, it can be understood that the start time of the light emission at Position 2 is delayed as compared with Position 1. In this case, the delay is about 2 ns. Position 3 is located between Position 1 and Position 2.

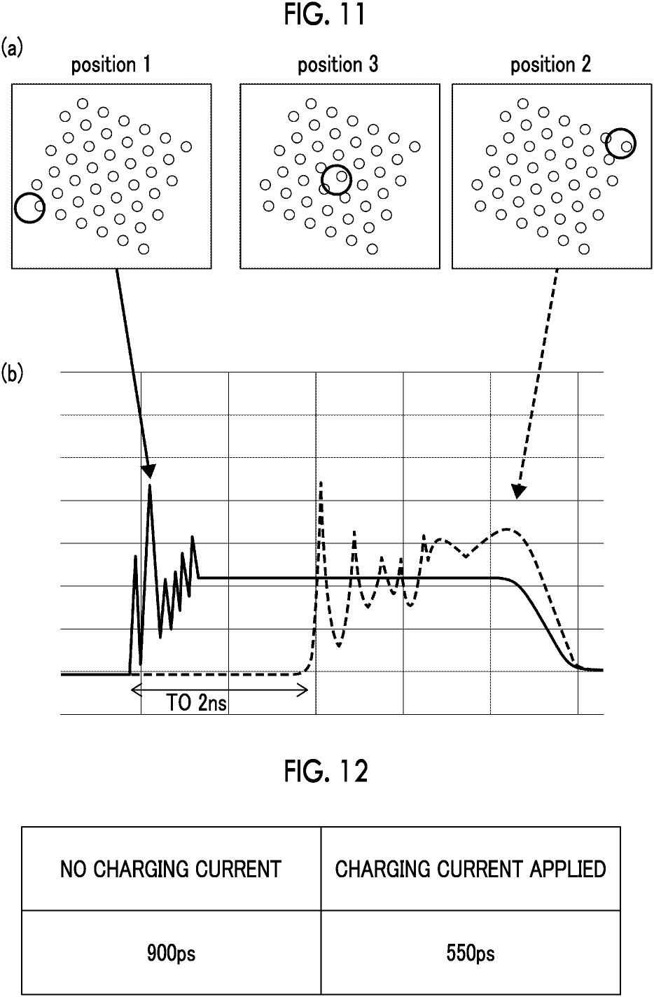

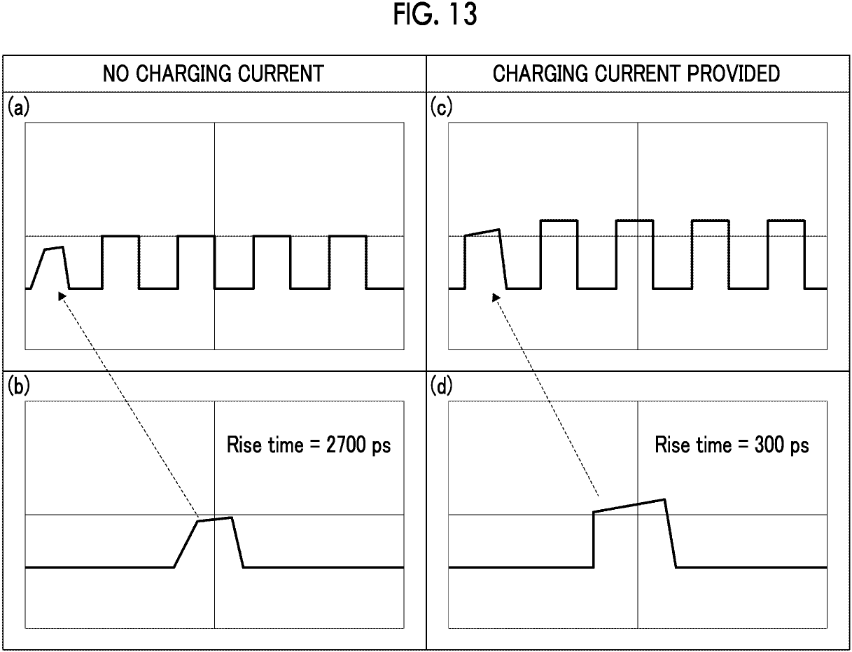

FIG. 12 is a diagram illustrating the effect in a case where the charging current is applied.

Here, FIG. 12 illustrates, for Position 1 and Position 2 in (b) of FIG. 11, the results obtained by measuring the light emission delay in a case where the charging current is caused not to flow and a case where the charging current has flowed.

In a case where the charging current is caused not to flow, the start time of the light emission at Position 2 is largely delayed as compared with Position 1. The delay at this time is about 900 ps.

Further, in a case where the charging current has been flowed, the delay in the start time of light emission at Position 2 becomes smaller than the delay at Position 1. The delay at this time is about 550 ps.

(a) to (d) of FIG. 13 are also diagrams illustrating the effect in a case where the charging current is applied. Here, the horizontal axis represents the time and the vertical axis represents the amount of emitted light.

Here, (a) to (d) of FIG. 13 illustrate a case where a high frequency is applied to blink the vertical cavity surface emitting laser VCSEL at a high speed. Thus, the waveform of light emission becomes a pulse wave.

Among (a) to (d) of FIG. 13, (a) of FIG. 13 illustrates the effect in a case where the charging current is caused not to flow. Further, (b) of FIG. 13 is a partially enlarged view of a place pointed out by the arrow in (a) of FIG. 13. In this case, it can be understood that the waveform of the first pulse is different from the waveform of the second and subsequent pulses. Such a difference in waveform is caused due to the delay in the start time of the light emission described above. In this case, the delay in the start time of the light emission is about 2700 ps.

On the other hand, (c) of FIG. 13 illustrates the effect in a case where the charging current has flowed. Further, (d) of FIG. 13 is a partially enlarged view of a place pointed out by the arrow in (c) of FIG. 13. In this case, the waveform of the first pulse is substantially identical to the waveform of the second and subsequent pulses. This is caused due to the small delay in the start time of the light emission described above. In this case, the delay in the start time of the light emission is about 300 ps.

In (a) and (b) of FIG. 13, in a case where the vertical cavity surface emitting laser VCSEL is used at a high frequency, the first pulse is not used and the second and subsequent pulses can be used as described with reference to FIG. 7. That is, the first pulse is regarded as a step for applying the charging current, and the second and subsequent pulses are used as a step after the charging current has flowed by the first pulse. In this case, the first pulse emits light as in the case of FIG. 8B, but it does not have to emit light as in the case of FIG. 8A. As described above, in a case where the vertical cavity surface emitting laser VCSEL is operated at a high frequency, it is possible to apply the charging current by using a pulse wave.

The charging current may be changed for each block B. Thus, it is possible to reduce the uneven light emission for each block B. The charging current for each block B is stored in, for example, the drive unit 50. The drive unit 50 changes the time and the current value for applying the charging current to apply the stored charging current.

Further, the charging current may be calibrated by using a white plate or the like. That is, the white plate is disposed so that the distance from the light emitting unit 22 of the information processing apparatus 1 is substantially equal, and the distance to the white plate is measured by irradiating the white plate with light. Then, the drive unit 50 calculates the charging current and sets it for each block B so that the distances are the same. In this case, the drive unit 50 also functions as a setting unit that sets a current required for charging the drive thyristor S as the charging current from the information regarding the light received by the 3D sensor 5.

In the present exemplary embodiment, the light emission delay of the vertical cavity surface emitting laser VCSEL is reduced by applying the charging current. In this case, since the light emission is less likely to be delayed, the amount of emitted light of the vertical cavity surface emitting laser VCSEL is less likely to decrease. Thus, in particular, as described above, in a case where the plurality of vertical cavity surface emitting lasers VCSELs are lit, the amount of emitted light is likely to be uniform regardless of the distance from the power feeding point, and the uneven light emission is reduced.

Further, even though the charging current is very small as compared with a drive current used in a case where the vertical cavity surface emitting laser VCSEL is actually lit, the effect is obtained. The charging current is, for example, about ⅒ to 1/15 of the oscillation threshold value of the vertical cavity surface emitting laser VCSEL.

### Structure of Light Emitting Unit 22

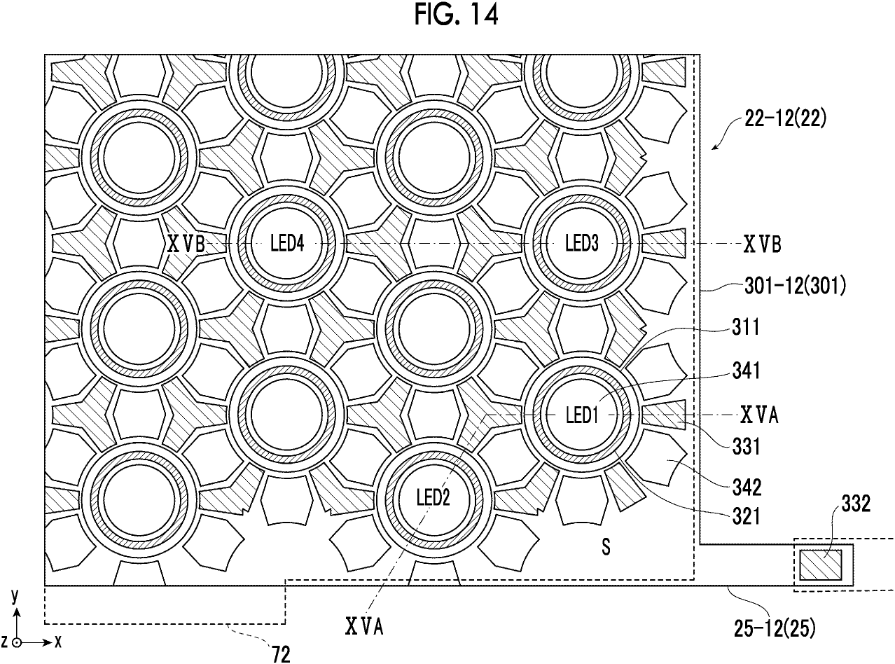

The light source 20 is configured with a semiconductor material capable of radiating light. For example, the light source 20 is configured with a GaAs-based compound semiconductor. Then, as illustrated in a cross-sectional view described later (see FIG. 14 described later), a semiconductor layer stacked body in which a plurality of GaAs-based compound semiconductor layers are stacked on an n-type GaAs substrate 80 is configured. The light source 20 is configured by separating the semiconductor layer stacked body into a plurality of islands. A region left in the shape of an island is called an island. A method of separating elements by etching the semiconductor layer stacked body in an island shape is referred to as mesa etching.

The light emitting units 22 are formed on islands 301 separated from each other, respectively. The islands 301 corresponding to the light emitting units 22-1, 22-2, and the like are referred to as islands 301-1, 301-2, and the like.

FIG. 14 is an enlarged plan view illustrating the light emitting unit 22. FIG. 14 is an enlarged view of a portion of the light emitting unit 22-12 (islands 301-12) in the light source 20 illustrated in FIG. 4. Description will be made below while the light emitting unit 22-12 is referred to as the light emitting unit 22, and the island 301-12 is referred to as the island 301. An x-direction, a y-direction, and a z-direction are similar to FIG. 4.

FIG. 14 illustrates a plurality of light emitting diodes LED. Here, four light emitting diodes LED are denoted by the reference signs LED1 to LED4. First, the planar structure of the light emitting unit 22 will be described focusing on the light emitting diode LED1 located at the lower right of the surface of paper. The light emitting diode LED1 will be described as the light emitting diode LED without distinguishing the light emitting diode LED1. The above description is similarly applied to the following description.

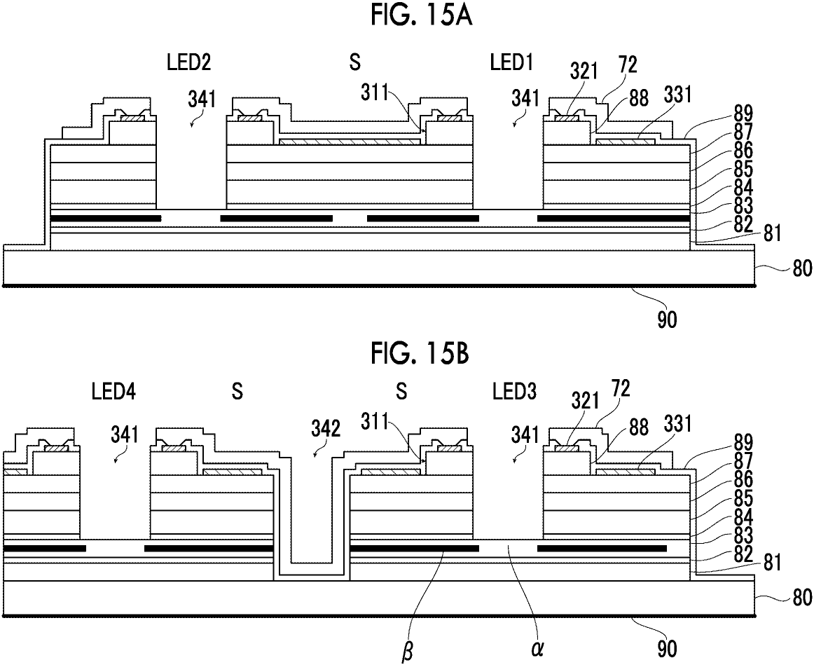

In the light emitting diode LED, the circular portion in the center refers to a light radiation port 341 of the light emitting diode LED. A region 311 (see FIGS. 15A and 15B described later) of the p-anode layer 88 of the drive thyristor S is provided to surround the light radiation port 341. A p-ohmic electrode 321 is provided on the region 311. Further, six holes (trench) 342 and six gate electrodes 331 are provided on the outside of the region 311. The gate electrode 331 is provided on the n-gate layer 87, which will be described later. Some gate electrodes 331 are connected to the gate electrodes 331 of the adjacent light emitting diode LED.

The n-gate layer 87 is drawn out to the switching unit 23 side, and a gate electrode 332 connected to the signal terminal 24 is provided at the end portion of the n-gate layer 87. The gate electrode 332 is connected to the signal terminal 24-12 of the switching unit 23 (see FIG. 4). The portion of the n-gate layer 87, which has been drawn out to the switching unit 23 side functions as the wiring 25 (here, the portion corresponds to the wiring 25-12) .

The light emission electrode 72 is provided to cover the light emitting unit 22 except for the light radiation port 341. The light emission electrode 72 is connected to the p-ohmic electrode 321 provided on the region 311 through a through-hole provided in an insulating layer 89 (see FIGS. 15A and 15B described later) . In FIG. 14, the light emission electrode 72 is indicated by the broken line.

FIGS. 15A and 15B are cross-sectional views illustrating the light emitting unit 22. FIG. 15A is a cross-sectional view taken along line XVA-XVA in FIG. 14, and FIG. 15B is a cross-sectional view taken along line XVB-XVB in FIG. 14. FIG. 15A is a cross-sectional view illustrating a portion of two light emitting diodes LED1 and LED2 adjacent to each other with the gate electrode 331 interposed between the two light emitting diodes LED1 and LED2. FIG. 15B is a cross-sectional view illustrating a portion of two light emitting diodes LED3 and LED4 adjacent to each other with the hole 342 interposed between the two light emitting diodes LED3 and LED4.

As illustrated in FIG. 15A, in the light emitting unit 22, an n-type cathode layer (referred to as an n-cathode layer below, and the same applies the following) 81, a light emitting layer 82, and a p-type anode layer (p-anode layer) 83 that form the light emitting diode LED are stacked on the n-type GaAs substrate 80. That is, the light emitting diode LED is configured with the stacked n-cathode layer 81 as a cathode, the light emitting layer 82 as a light emitting layer, and the p-anode layer 83 as an anode.

Then, a tunnel junction layer 84 is stacked on the p-anode layer 83.

Then, an n-type cathode layer (n-cathode layer) 85, a p-type gate layer (p-gate layer) 86, an n-type gate layer (n-gate layer) 87, and a p-type anode layer (p-anode layer) 88 that form the drive thyristor S are stacked on the tunnel junction layer 84. That is, the drive thyristor S is configured with the stacked n-cathode layer 85 as a cathode, the p-gate layer 86 as a p-gate, the n-gate layer 87 as an n-gate, and the p-anode layer 88 as an anode.

The light emitting diode LED is configured in a manner that the p-anode layer 88, the n-gate layer 87, the p-gate layer 86, the n-cathode layer 85, and the tunnel junction layer 84 of the drive thyristor S, which have been stacked on the upper side, are removed by etching, and the p-anode layer 83 is exposed. That is, light is radiated from the exposed p-anode layer 83. The exposed p-anode layer 83 functions as the light radiation port 341.

The drive thyristor S is configured by the n-cathode layer 85, the p-gate layer 86, the n-gate layer 87, and the p-anode layer 88 that are left around the light radiation port 341 of the light emitting diode LED. The tunnel junction layer 84, the p-anode layer 83, the light emitting layer 82, and the n-cathode layer 81 that form the light emitting diode LED are present on the substrate 80 side of the drive thyristor S. That is, the light emitting diode LED and the drive thyristor S are stacked through the tunnel junction layer 84 and are connected in series.

The tunnel junction layer 84 is provided between the p-anode layer 83 of the light emitting diode LED and the n-cathode layer 85 of the drive thyristor S. That is, in a case where the tunnel junction layer 84 is not provided, the p-anode layer 83 of the light emitting diode LED and the n-cathode layer 85 of the drive thyristor S are in a reverse bias state. Thus, it is difficult for a current to flow from the n-cathode layer 85 of the drive thyristor S to the p-anode layer 83 of the light emitting diode LED. The tunnel junction layer 84 refers to a junction between a p⁺⁺ layer on the p-anode layer 83 side of the light emitting diode LED and an n⁺⁺ layer on the n-cathode layer 85 side of the drive thyristor S. The p⁺⁺ layer is obtained by adding p-type impurities at a high concentration, and the n⁺⁺ layer is obtained by adding n-type impurities at a high concentration. In the tunnel junction layer 84, the width of the depleted region is narrow. Thus, electrons are tunneled from the conduction band on the n⁺⁺ layer side to the valence band on the p⁺⁺ layer side in the reverse bias state. Thus, a current easily flows from the n-cathode layer 85 of the drive thyristor S to the p-anode layer 83 of the light emitting diode LED. Meanwhile, in a case where a current flows from the gate electrode 331 to the n-gate layer 87, the drive thyristor S may emit a slight amount of light. In a case where the drive thyristor S emits light, and the surrounding drive thyristor S, which does not include the common gate layer or electrode, receives light and mistakes the received light for a signal, a current may flow in the p-anode layer 83 of the light emitting diode LED, which has not originally been planned to emit light, and the light emitting diode LED may emit light. In particular, in a case where the light emission electrode 72 is provided in common to all the light emitting units 22, this occurs largely. Therefore, in the present exemplary embodiment, the configuration is made such that the band gap of the layer that emits light such as the gate layer of the drive thyristor S is larger than the band gap of the layer having a low Al composition in an AlGaAs layer forming a lower distributed Bragg reflector. With such a configuration, for example, even though light is emitted from the drive thyristor S, the emitted light is absorbed by the DBR, and an occurrence of a situation in which light reaches another drive thyristor S is suppressed. Thus, the erroneous lighting is suppressed.

Then, the p-ohmic electrode 321 that comes into ohmic contact with the p-anode layer 88 is formed on the p-anode layer 88. The p-ohmic electrode 321 is connected to the light emission electrode 72 through a through-hole formed in the insulating layer 89.

Further, the gate electrode 331 that comes into ohmic contact with the n-gate layer 87 is formed on the n-gate layer 87 that is exposed by removing a portion of the p-anode layer 88 by etching. The gate electrode 331 reduces the resistance of the exposed n-gate layer 87.

The light emission electrode 72 and the gate electrode 331 are insulated from each other through the insulating layer 89.

As illustrated in FIG. 15A, the n-cathode layer 81, the light emitting layer 82, the p-anode layer 83, the tunnel junction layer 84, the n-cathode layer 85, the p-gate layer 86, the n-gate layer 87, and the p-anode layer 88, that form the light emitting diode LED and the drive thyristor S, are continuous between the light radiation port 341 of the light emitting diode LED1 and the light radiation port 341 of the light emitting diode LED2. The light emitting diode LED1 and the light emitting diode LED2 are adjacent to each other with the gate electrode 331 interposed between the light emitting diode LED1 and the light emitting diode LED2.

As illustrated in FIG. 15B, the light radiation port 341 of the light emitting diode LED3 and the light radiation port 341 of the light emitting diode LED4 are adjacent to each other with the hole 342 interposed between the light emitting diode LED3 and the light emitting diode LED4. The hole 342 is provided by removing the p-anode layer 88, the n-gate layer 87, the p-gate layer 86, the n-cathode layer 85, the tunnel junction layer 84, the p-anode layer 83, the light emitting layer 82, and the n-cathode layer 81. Then, by oxidizing a current constriction layer included in the p-anode layer 83, through the hole 342, the portion close to the hole 342 is set as a current blocking portion β in which the current is less likely to flow. On the other hand, the portion far from the hole 342 remains unoxidized. That is, the portion that has not been oxidized functions as a current passing portion α through which the current flows. A plurality of holes 342 are provided around the light radiation port 341 at positions surrounding the light radiation port 341. Thus, the current passing portion α is formed in a form close to a circle. The light radiation port 341 is provided corresponding to the current passing portion α. Therefore, even though the n-cathode layer 81, the p-anode layer 83, and the light emitting layer 82 are continuously provided for a plurality of light emitting diodes LED in the light emitting unit 22, each light emitting diode LED emits light at the portion corresponding to the light radiation port 341.

On the other hand, as illustrated in FIG. 15A, the n-cathode layer 85, the p-gate layer 86, the n-gate layer 87, and the p-anode layer 88 forming the drive thyristor S are continuous between the light emitting diodes LED. Thus, the drive thyristor S operates for each light emitting unit 22. That is, as illustrated in FIG. 6, in the light emitting unit 22, one drive thyristor S is provided for the plurality of light emitting diodes LED.

As illustrated at the right end portions of FIGS. 14A and 14B, the p-anode layer 88, the n-gate layer 87, the p-gate layer 86, the n-cathode layer 85, the tunnel junction layer 84, the p-anode layer 83, the light emitting layer 82, and the n-cathode layer 81 are removed between the light emitting units 22, that is, between the islands 301. That is, the p-anode layer 83, the light emitting layer 82, and the n-cathode layer 81 forming the light emitting unit 22, and the p-anode layer 88, the n-gate layer 87, the p-gate layer 86, and the n-cathode layer 85 forming the drive thyristor S are discontinuous between the islands 301. Thus, each light emitting unit 22 is individually controlled to emit light.

### Structure of Semiconductor Layer Stacked Body

The n-cathode layer 81, the light emitting layer 82, the p-anode layer 83, the tunnel junction layer 84, the n-cathode layer 85, the p-gate layer 86, the n-gate layer 87, and the p-anode layer 88, which are stacked on the substrate 80, are semiconductor layer stacked bodies. The n-cathode layer 81, the light emitting layer 82, and the p-anode layer 83 are semiconductor layers forming the light emitting diode LED. The n-cathode layer 85, the p-gate layer 86, the n-gate layer 87, and the p-anode layer 88 are semiconductor layers forming the drive thyristor S.

Such semiconductor layer stacked bodies will be described below in order.

### Substrate 80

The substrate 80 will be described by using n-type GaAs as an example, but may be p-type GaAs or intrinsic (i) GaAs to which no impurities are added. Further, a semiconductor substrate consisting of InP, GaN, InAs, the other III-V group materials, II-VI group materials, a crystal substrate of sapphire, Si, and Ge, and the like may be used as the substrate 80. In a case where the substrate is changed, as the material monolithically stacked on the substrate, a material that substantially matches the lattice constant of the substrate (including a strain structure, a strain relaxation layer, and a metamorphic growth) is used. As an example, InAs, InAsSb, GaInAsSb, and the like are used on an InAs substrate. InP, InGaAsP, and the like are used on an InP substrate. GaN, AlGaN, InGaN are used on a GaN substrate or a sapphire substrate. Si, SiGe, GaP, and the like are used on a Si substrate. In a case where the substrate 80 has an electrically insulating property, it is required to separately provide an electrode for supplying a potential to the n-cathode layer 81. Further, in a case where the semiconductor layer stacked body excluding the substrate 80 is attached to another support substrate and the semiconductor layer stacked body is provided on the other support substrate, it is not required that the lattice constant of the semiconductor layer stacked body matches the lattice constant of the support substrate.

### Semiconductor Layer Forming Light Emitting Diode LED

Here, the light emitting diode LED will be described as being a VCSEL.

The n-cathode layer 81 forms an n-type lower distributed Bragg reflector (DBR) in which AlGaAs layers having different Al compositions alternately overlap. The light emitting layer 82 is configured as an active region including a quantum well layer sandwiched between an upper spacer layer and a lower spacer layer. The p-anode layer 83 is configured as an upper distributed Bragg reflector in which AlGaAs layers having different Al compositions alternately overlap. The distributed Bragg reflector is referred to as a DBR below. The optical output of one VCSEL is 4 mW to 8 mW, which is higher than the optical outputs of other laser diodes.

The n-type lower DBR forming the n-cathode layer 81 is configured as a stacked body in which an Al_{0.9}Ga_{0.1}As layer and a GaAs layer are paired. Each layer of the lower DBR has a thickness of λ/4nᵣ (where λ indicates the oscillation wavelength, and nᵣ indicates the refractive index of a medium), and is alternately stacked for 40 cycles. Silicon (Si), which is an n-type impurity, is doped as a carrier. The carrier concentration is, for example, 3 × 10¹⁸ cm⁻³.

The lower spacer layer forming the light emitting layer 82 is an undoped Al_{0.6}Ga_{0.4}As layer. The quantum well active layer is an undoped InGaAs quantum well layer and an undoped GaAs barrier layer. The upper spacer layer is an undoped Al_{0.6}Ga_{0.4}As layer.

The p-type upper DBR forming the p-anode layer 83 is configured as a stacked body in which a p-type A1_{0.9}Ga_{0.1}As layer and a GaAs layer are paired. Each layer of the upper DBR has a thickness of λ/4nr and is alternately stacked for 29 cycles. Carbon (C), which is a p-type impurity, is doped as a carrier. The carrier concentration is, for example, 3 × 10¹⁸ cm⁻³. A p-type AlAs current constriction layer is provided at or inside the lowermost layer of the upper DBR.

The p-type AlAs has an oxidation rate higher than AlGaAs, and an oxidation region is oxidized inward from the side surface of the hole 342. Al is oxidized to form Al₂O₃, and thus the electric resistance is increased and the current blocking portion β is formed. The current constriction layer may be a layer in which Al is oxidized to form Al₂O₃, such as p-type AlGaAsGaAs having a high Al impurity concentration instead of AlAs. The current blocking portion β may be formed by driving hydrogen ions (H⁺) into a semiconductor layer of AlGaAs or the like (H⁺ ion driving).

### Tunnel Junction Layer 84

The tunnel junction layer 84 refers to a junction between a p⁺⁺ layer in which p-type impurities are added at a high concentration and an n⁺⁺ layer in which n-type impurities are added at a high concentration. The n⁺⁺ layer and the p⁺⁺ layer have a high impurity concentration of, for example, 1 × 10²⁰/cm³. The impurity concentration of the normal junction is 10¹⁷/cm³ to 10¹⁸/cm³. The combination of the p⁺⁺ layer and the n⁺⁺ layer (referred to as a p⁺⁺ layer/n⁺⁺ layer below) is, for example, p⁺⁺GaAs/n⁺⁺GaInP, p⁺⁺A1GaAs/n⁺⁺GaInP, p⁺⁺GaAs/n⁺⁺GaAs, p⁺⁺AlGaAs/n⁺⁺AlGaAs, p⁺⁺InGaAs/n⁺⁺InGaAs, p⁺⁺GaInAsP/n⁺⁺GaInAsP, and p⁺⁺GaAsSb/n⁺⁺GaAsSb. The combinations may be changed from each other.

### Semiconductor Layer Forming Drive Thyristor S

The n-cathode layer 85 is, for example, an n-type Al_{0.9}GaAs having an impurity concentration of 1 × 10¹⁸/cm³. The Al composition may be changed in a range of 0 to 1.

The p-gate layer 86 is, for example, a p-type Al_{0.9}GaAs having an impurity concentration of 1 × 10¹⁷/cm³. The Al composition may be changed in a range of 0 to 1.

The n-gate layer 87 is, for example, an n-type Al_{0.9}GaAs having an impurity concentration of 1 × 10¹⁷/cm³. The Al composition may be changed in a range of 0 to 1.

The p-anode layer 88 is, for example, a p-type Al_{0.9}GaAs having an impurity concentration of 1 × 10¹⁸/cm³. The Al composition may be changed in a range of 0 to 1.

### Manufacturing Method of Light Source 20

The light source 20 is manufactured as follows.

The n-cathode layer 81, the light emitting layer 82, the p-anode layer 83, the tunnel junction layer 84, the n-cathode layer 85, the p-gate layer 86, the n-gate layer 87, and the p-anode layer 88 are stacked on the substrate 80 in this order. Then, the p-anode layer 88, the n-gate layer 87, the p-gate layer 86, the n-cathode layer 85, the tunnel junction layer 84, the p-anode layer 83, the light emitting layer 82, and the n-cathode layer 81 are etched to form a portion and the hole 342 for separating light emitting units 22.

In an oxidization atmosphere, the current constriction layer is oxidized in the p-anode layer 83 from the side surface of the hole 342 to form the current blocking portion β.

Further, a portion of the p-anode layer 88 is etched to expose the surface of the n-gate layer 87. The p-ohmic electrode 321 is formed on the p-anode layer 88, and the gate electrode 331 that comes into ohmic contact with the n-gate layer 87 is formed on the n-gate layer 87. The p-ohmic electrode 321 is configured of, for example, Au (AuZn) containing Zn that makes ohmic contact with the p-type AlGaAs. The gate electrode 331 is configured of, for example, Au (AuGe) containing Ge that makes ohmic contact with the n-type AlGaAs.

Then, the insulating layer 89 is formed on the front surface. The insulating layer 89, the p-anode layer 88, the n-gate layer 87, the p-gate layer 86, the n-cathode layer 85, and the tunnel junction layer 84 are etched to form the light radiation port 341. The insulating layer 89 is, for example, SiO₂, SiN, or the like.

A through-hole is formed in the insulating layer 89 at the portion of the p-ohmic electrode 321 to form the light emission electrode 72. Simultaneously with the light emission electrode 72, the signal terminal 24 of the switching unit 23 and the wiring for connecting the signal terminal 24 and the n-gate layer 87 are formed.

The light source 20 may be manufactured by replacing the above steps. For example, the light radiation port 341 may be formed before the insulating layer 89 is formed. In this manner, the light radiation port 341 is covered and protected with the insulating layer 89. In this case, a layer that transmits light of the light emitting diode LED is used as the insulating layer 89.

As described above, in a case where the light emitting diode LED and the drive thyristor S are stacked, the light emission of the light emitting diode LED is controlled by supplying the switching signal φf to the drive thyristor S. That is, the light emission of the light emitting diode LED is easily controlled in comparison to a case where the light emitting diode LED and the drive thyristor S are not stacked.

In the present exemplary embodiment, a light emitting diode LED, which is an example of a light emitting element, is provided on the substrate 80, and a drive thyristor S is stacked on the light emitting diode LED. The drive thyristor S may be provided on the substrate 80, and the light emitting diode LED may be stacked on the drive thyristor S.

Further, in the present exemplary embodiment, the n-type substrate 80 is used, but a light source 20 having opposite polarities may be configured as the p-type substrate. At this time, the light emitting diode LED may be provided on the substrate, and the drive thyristor S may be stacked on the light emitting diode LED. The drive thyristor S may be provided on the substrate 80, and the drive thyristor S may be stacked on the drive thyristor S.

In the present exemplary embodiment, the light emitting unit 22 is configured such that the light emitting elements (light emitting diodes LED in the present exemplary embodiment) of the identical light emitting unit 22 are adjacent to each other, and, in this manner, the light emitting unit 22 is easily configured. However, it is not required for the light emitting elements to be arranged together, and the light emitting elements connected to the identical signal terminal 24 of the switching unit 23 may be regarded as one light emitting unit 22.

In the present exemplary embodiment, an example in which the light emitting device 4 is utilized together with the 3D sensor 5 has been described, but the present invention is not limited to the above example. The present exemplary embodiment may be applied to a light emitting device used for optical transmission. In this case, a combination with an optical transmission line may be performed. Light switched by the switching unit may be put into the identical optical transmission line, or may be put into different optical transmission lines.

In the present exemplary embodiment, an example in which the reflected light obtained by reflecting light emitted from the light emitting unit 22 by a target is used has been described, but the present exemplary embodiment may be applied to a configuration in which direct light is used, such as for optical transmission.

In the present exemplary embodiment, a case where the current required for charging the drive thyristor S is set as the charging current from the information regarding the light received by the 3D sensor 5 has been described, but a light receiving unit such as a photodiode may be provided separately from the 3D sensor 5.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a light emitting unit that includes a light emitting element having a function of a thyristor; and
a drive unit that performs, before a period in which light emitted from the light emitting unit is used, control such that a predetermined current or larger flows in the thyristor of the light emitting unit.

2. The light emitting device according to claim 1,
wherein the drive unit sets a time for causing the predetermined current or larger to flow, to be longer than a time for causing a current to flow in a case where the light emitting element emits light.

3. The light emitting device according to claim 1,
wherein the drive unit causes the light emitting unit to emit light a plurality of times during the period in which the light emitted from the light emitting unit is used, and
performs control to align a time interval from application of the predetermined current or larger until first light emission among the plurality of times of light emission is performed, with respective time intervals for the plurality of times of light emission.

4. The light emitting device according to claim 2,
wherein the drive unit causes the light emitting unit to emit light a plurality of times during the period in which the light emitted from the light emitting unit is used, and
performs control to align a time interval from application of the predetermined current or larger until first light emission among the plurality of times of light emission is performed, with respective time intervals for the plurality of times of light emission.

5. The light emitting device according to claim 1,
wherein the light emitting unit has a structure in which light-emitting-element groups, in each in which a plurality of the light emitting elements emit light together, are arranged in a form of a plurality of surfaces, and
the drive unit controls light emission for each light-emitting-element group.

6. The light emitting device according to claim 2,
wherein the light emitting unit has a structure in which light-emitting-element groups, each in which a plurality of the light emitting elements emit light together, are arranged in a form of a plurality of surfaces, and
the drive unit controls light emission for each light-emitting-element group.

7. The light emitting device according to claim 5,
wherein the drive unit performs control so that in a case where the light-emitting-element group emits light, the predetermined current or larger flows in the thyristor in the light-emitting-element group, and in a case where the light-emitting-element group does not emit light, the predetermined current or larger does not flow.

8. The light emitting device according to claim 6,
wherein the drive unit performs control so that in a case where the light-emitting-element group emits light, the predetermined current or larger flows in the thyristor in the light-emitting-element group, and in a case where the light-emitting-element group does not emit light, the predetermined current or larger does not flow.

9. The light emitting device according to claim 5,
wherein the drive unit changes an amount of the predetermined current for each light-emitting-element group.

10. The light emitting device according to claim 6,
wherein the drive unit changes an amount of the predetermined current for each light-emitting-element group.

11. The light emitting device according to claim 9, further comprising:
a light receiving unit that receives reflected light from a measurement target object irradiated with the light; and
a setting unit that sets, as the predetermined current, a current required to charge the thyristor from information regarding the light received by the light receiving unit.

12. The light emitting device according to claim 10, further comprising:
a light receiving unit that receives reflected light from a measurement target object irradiated with the light; and
a setting unit that sets, as the predetermined current, a current required to charge the thyristor from information regarding the light received by the light receiving unit.

13. The light emitting device according to claim 1,
wherein the light emitting element includes a vertical cavity surface emitting laser, and
the predetermined current is equal to or larger than a threshold current for causing the vertical cavity surface emitting laser to emit light.

14. The light emitting device according to claim 1,
wherein the light emitting element is a light emitting element that emits light in relaxation oscillation,
the predetermined current is a current small enough for causing the light emitting unit to emit light in the relaxation oscillation even after the predetermined current has flowed, and
the drive unit does not cause the light emitting element to emit light.

15. The light emitting device according to claim 14,
wherein the thyristor transitions to an ON state by the predetermined current.

16. A light emitting device comprising:
a light emitting unit that includes a light emitting element having a function of a thyristor;
a light receiving unit that receives light emitted from the light emitting unit;
a drive unit that performs control such that a current flows so that light is emitted from the light emitting unit a plurality of times; and
a control unit that prevents first emitted light among rays of light emitted from the light emitting unit from being used as a light reception result of the light receiving unit.

17. A measurement apparatus comprising:
the light emitting device according to claim 1; and
a processing unit that processes information regarding light obtained by receiving reflected light from a measurement target object irradiated with light from the light emitting device, and measures a distance from the light emitting device to the measurement target object or a shape of the measurement target object.

18. A measurement apparatus comprising:
the light emitting device according to claim 2; and
a processing unit that processes information regarding light obtained by receiving reflected light from a measurement target object irradiated with light from the light emitting device, and measures a distance from the light emitting device to the measurement target object or a shape of the measurement target object.

19. A measurement apparatus comprising:
the light emitting device according to claim 3; and a processing unit that processes information regarding light obtained by receiving reflected light from a measurement target object irradiated with light from the light emitting device, and measures a distance from the light emitting device to the measurement target object or a shape of the measurement target object.

20. A measurement apparatus comprising:
the light emitting device according to claim 4; and
a processing unit that processes information regarding light obtained by receiving reflected light from a measurement target object irradiated with light from the light emitting device, and measures a distance from the light emitting device to the measurement target object or a shape of the measurement target object.
